(19) United States
(12) Patent Application Publication
(10) Pub. No.: US 2021/0057277 A1
(43) Pub. Date: Feb. 25, 2021

(54) DISCRETE PIECE FORMING DEVICE AND DISCRETE PIECE FORMING METHOD

(71) Applicant: LINTEC CORPORATION, Tokyo (JP)

(72) Inventor: Yoshiaki SUGISHITA, Tokyo (JP)

(73) Assignee: LINTEC CORPORATION, Tokyo (JP)

(21) Appl. No.: 17/092,285

(22) Filed: Nov. 8, 2020

Related U.S. Application Data
(63) Continuation of application No. PCT/JP2018/047267, filed on Dec. 21, 2018.

(30) Foreign Application Priority Data
May 9, 2018 (JP) 2018-090981

(51) Int. Cl. H01L 21/78; C09J 7/40; C09J 7/30; B32B 7/02; B32B 7/12

(52) U.S. Cl. CPC H01L 21/78; C09J 7/40; C09J 7/30; C09J 2301/30; B32B 7/12; C09J 2203/326; C09J 2301/208; B32B 7/02

(57) ABSTRACT

A discrete piece forming device EA that forms discrete pieces CP by dividing a work WF into pieces includes: a sheet pasting unit 10 which pastes, on the work WF, an adhesive sheet AS containing swell grains SG that swell when predetermined energy IR is applied; a modified part forming unit 20 which forms modified parts MT in the work WF to form, in the work WF, predefined discrete piece areas WFP each surrounded by the modified parts MT; and a dividing unit 30 which divides the work WF into pieces by forming, in the work WF, cracks CK starting from the modified parts MT by applying external force to the work WF, to form the discrete pieces CP. The dividing unit 30 applies the energy IR to parts of the adhesive sheet AS to swell the swell grains SG contained in adhesive sheet parts ASP to which the energy IR has been applied, thereby displacing the predefined discrete piece areas WFP pasted on the adhesive sheet parts ASP to form the discrete pieces CP.

### BACKGROUND OF THE INVENTION

### Field of the Invention

The present invention relates to a discrete piece forming device and a discrete piece forming method, and for example, relates to a device and a method for forming many discrete pieces by dividing a work such as a semiconductor wafer into small pieces.

### Description of the Related Art

Examples of a discrete piece forming device include a device that divides a work such as a semiconductor wafer along modified parts formed in the work, into pieces to form discrete pieces. This device forms die bond chips (discrete pieces) by dividing the work into pieces along the modified parts by pulling a dicing tape pasted on the work.

### SUMMARY OF THE INVENTION

The present invention disclosed and claimed herein, in one aspect thereof, comprises a discrete piece forming device. The device comprises:

a sheet pasting unit which pastes, on a work, an adhesive sheet. containing a swell grain that swells when predetermined energy is applied;

a modified part forming unit which forms a modified part in the work to form, in the work, a predefined discrete piece area surrounded by the modified part or surrounded by the modified part and an outer edge of the work; and

a dividing unit which divides the work into pieces by forming, in the work, a crack starting from the modified part by applying external force to the work, to form a discrete piece, wherein the dividing unit applies the energy to part of the adhesive sheet to swell the swell grain contained in an adhesive sheet part to which the energy has been applied, thereby displacing the predefined discrete piece area pasted on the adhesive sheet part to form the discrete piece.

Further scope of applicability of the present invention will become apparent from the detailed description given hereinafter. The detailed description and embodiments are only given as examples though showing to preferred embodiments of the present invention, and therefore, from the contents of the following detailed description, changes and modifications of various kinds within the spirits and scope of the invention will become apparent to those skilled in the art.

### BRIEF DESCRIPTION OF THE DRAWINGS

The present invention will be fully understood from the following detailed description and the accompanying drawings. The accompanying drawings only show examples and are not intended to restrict the present invention. In the accompanying drawings:

FIG. 1A is an explanatory view of a discrete piece forming device according to one embodiment;

FIG. 1B is an explanatory view of the discrete piece forming device according to the embodiment;

FIG. 2A is an explanatory view of the operation of the discrete piece forming device;

FIG. 2B is an explanatory view of the operation of the discrete piece forming device;

FIG. 2C is an explanatory view of the operation of the discrete piece forming device;

FIG. 2D is an explanatory view of the operation of the discrete piece forming device;

FIG. 3A is an explanatory view of a modified example;

FIG. 3B is an explanatory view of a modified example; and

FIG. 3C is an explanatory view of a modified example.

### DETAILED DESCRIPTION

An embodiment will be hereinafter described with reference to the drawings.

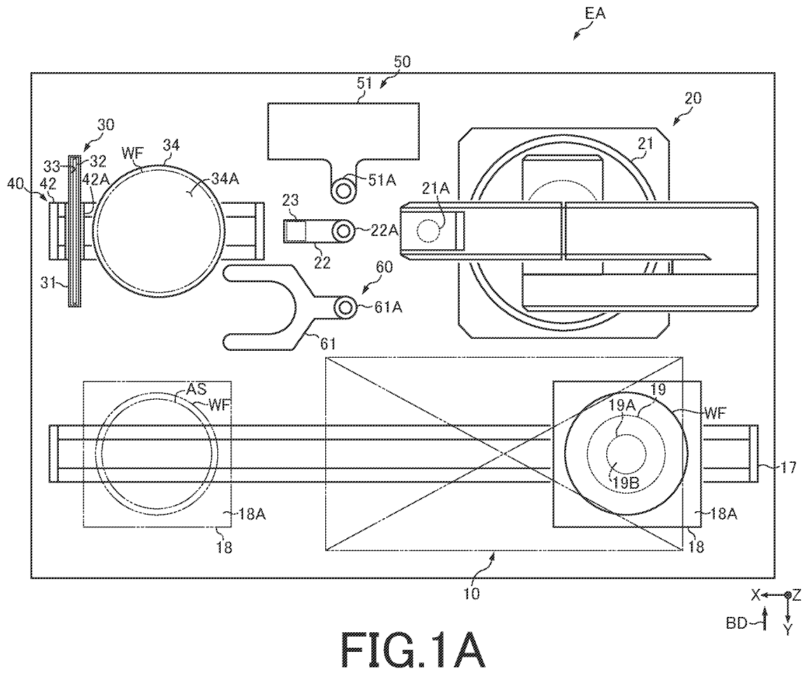

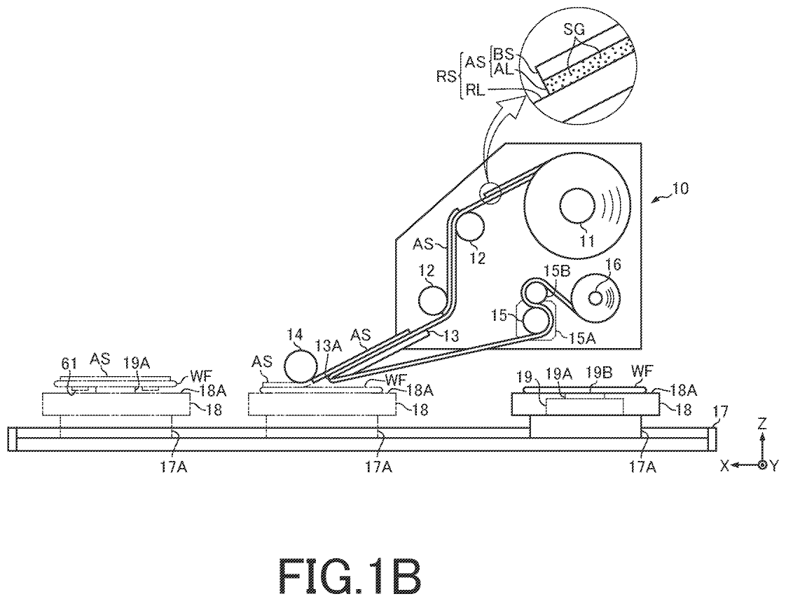

It should be noted that X-axis, Y-axis, and Z-axis in the embodiment are orthogonal to one another, where the X-axis and the Y-axis are within a predetermined plane while the Z-axis is orthogonal to the predetermined plane. Further, in the embodiment, FIG. 1A as viewed from the arrow BD direction parallel to the Y-axis is used as a reference for direction, and when a direction is mentioned without any designation of a drawing, an “upper” direction means a direction indicated by an arrow along the Z-axis, a “lower” direction means a direction opposite the upper direction, a “left” direction means a direction indicated by an arrow along the X-axis, a “right” direction means a direction opposite the “left” direction, a “front” direction means a direction toward the near side in FIG. 1A in terms of a direction parallel to the Y-axis, and a “rear” direction means a direction opposite the “front” direction.

A discrete piece forming device EA divides a semiconductor wafer (hereinafter, also referred to simply as a “wafer”) WF as a work into pieces to form semiconductor chips (hereinafter, also referred to simply as “chips”) CP as discrete pieces, and includes: a sheet pasting unit 10 which pastes, on the wafer WF, an adhesive sheet AS containing swell grains SG that swell when infrared rays IR as predetermined energy are applied; a modified part forming unit 20 which forms modified parts MT in the wafer WF to form, in the wafer WF, predefined discrete piece areas WFP each surrounded by the modified parts MT; a dividing unit 30 which divides the wafer WF into pieces by forming, in the wafer WF, cracks CK shirting from the modified parts MT by applying external force to the wafer WF, to form the chips CP; a moving unit 40 which relatively moves the wafer WF and the dividing unit 30; a displacement inhibiting unit 50 which inhibits the displacement of parts, of the wafer WF, that have not yet been displaced by the dividing unit 30; and a wafer carrier unit 60 which carries the wafer WF.

The adhesive sheet AS includes a base BS and an adhesive layer AL, and the adhesive sheet AS is temporarily bonded to a release liner RL and the resultant is a raw sheet RS, and only the adhesive layer AL contains the swell grains SG.

The sheet pasting unit 10 includes: a support roller 11 which supports the raw sheet RS; guide rollers 12 which guide the raw sheet RS; a releasing plate 13 as a releasing unit which releases the adhesive sheet AS from the release liner RL by bending the release liner RL at its releasing edge 13A; a press roller 14 as a press unit which presses the adhesive sheet AS against the wafer WF to paste the adhesive sheet AS; a drive roller 15 which is supported by a not-illustrated output shaft of a rotary motor 15A as a drive device and sandwiches the release liner RL between itself and a pinch roller 15B; a recovering roller 16 as a recovering unit which constantly applies predetermined tension to the release liner RL present between itself and the pinch roller 15B and recovers the release liner RL; a wafer carrier table 18 which is supported by a slider 17A of a linear motor 17 as a drive device and has a support surface 18A on which the wafer WF can be held by being sucked by a not-illustrated pressure-reducing unit (holding unit) such as a pressure-reducing pump or a vacuum ejector; and a direct-acting motor 19 as a drive device which is in the wafer carrier table 18 and lifts up/down a lift table 19A. The lift table 19A has a support surface 19B on which the wafer WF can be held by being sucked by a not-illustrated pressure-reducing unit (holding unit) such as a pressure-reducing pump or a vacuum ejector.

The modified part forming unit 20 includes: what is called a multi-joint robot 21 as a drive device composed of a plurality of arms and capable of displacing an object supported by its tip arm 21A, which is a working part, to any position or any angle in its work range; a laser bracket 22 having a laser holding part 22A which is held by the multi-joint robot 21 when the tip arm 21A of the multi-joint robot 21 is inserted thereto; and a laser irradiator 23 which is supported by the laser bracket 22 and exposes the wafer WF to laser LS radiation to form the modified parts MT. The modified part forming unit 20 forms first modified parts MTY extending along the Y-axis direction as a first direction and second modified parts MTX extending along the X-axis direction as a second direction intersecting with the Y-axis direction, to form predefined discrete piece areas WFP each surrounded by the first modified parts MTY and the second modified parts MTX. Examples of the multi joint robot 21 include the multi-joint robot 111 exemplified in Japanese Patent Application Laid-open No. 2016-81974 which is explicitly incorporated in the present specification by reference.

The dividing unit 30 includes a light source box 31 supported by the moving unit 40, a light emitter 32 which is supported in the light source box 31 and emits infrared rays IR, a condenser plate 33 which condenses the infrared rays IR emitted by the light emitter 32, and a support table 34 able to transmit the infrared rays IR. The dividing unit 30 forms a line-shaped application area LG in which an application area of the infrared rays IR extends in a predetermined direction, at a position to which the infrared rays IR are applied, and applies the infrared rays IR to parts of the adhesive sheet AS to swell the swell grains SG contained in adhesive sheet parts ASP to which the infrared rays IR have been applied, thereby displacing the predefined discrete piece areas WFP pasted on the adhesive sheet parts ASP to form the chips CP. The support table 34 has a support surface 34A on which the wafer WF can be held by being sucked by a not-illustrated pressure-reducing unit (holding unit) such as a pressure-reducing pump or a vacuum ejector.

The moving unit 40 includes a rotary motor 41 as a drive device and a linear motor 42 as a drive device which is supported by an output shaft 41A of the rotary motor 41 and whose slider 42A supports the light source box 31. The moving unit 40 moves the line-shaped application area LG formed by the dividing unit 30 to make it parallel to the Y-axis direction and further moves the line-shaped application area LG to make it parallel to the X-axis direction.

The displacement inhibiting unit 50 includes: the multi joint robot 21 shared with the modified part forming unit 20; and a hold plate 51 having a hold plate holding part 51A which is held by the multi-joint robot 21 when the tip arm 21A of the multi joint robot 21 is inserted thereto.

The wafer carrier unit 60 includes: the multi-joint robot 21 shared with the modified part forming unit 20 and the displacement inhibiting unit 50; and a suction arm 61 as a holding unit which has a suction arm holding part 61A held by the multi-joint robot 21 when the tip arm 21A of the multi-joint robot 21 is inserted thereto and which is enabled to suction-hold the wafer WF by a not-illustrated pressure-reducing unit such as a pressure-reducing pump or a vacuum ejector.

The operation of the above-described discrete piece forming device EA will be described.

First, in the discrete piece forming device EA whose members are arranged at initial positions indicated by the solid lines in FIG. 1A, a user of the discrete piece forming device EA (hereinafter, referred to simply as a “user”) sets the raw sheet RS as illustrated in FIG. 1B, and thereafter inputs an operation start signal through a not-illustrated operation unit such as an operation panel or a personal computer. Then, the sheet pasting unit 10 drives the rotary motor 15A to feed out the raw sheet RS, and when a predetermined length of a feeding-direction leading end portion of the adhesive sheet AS at the head is released from the release liner RL at the releasing edge 13A of the releasing plate 13, the sheet pasting unit 10 stops driving the rotary motor 15A. Meanwhile, when the operation start signal is input to the discrete piece forming device EA, the wafer carrier unit 60 drives the multi joint robot 21 and makes the tip arm 21A inserted to the suction arm holding part 61A, so that the suction arm 61 is held by the multi joint robot 21.

Next, when the user or a not-illustrated carrier unit such as a multi-joint robot or a belt conveyor places the wafer WF on the wafer carrier table 18 as indicated by the solid line in FIG. 1A and FIG. 1B, the sheet pasting unit 10 drives the not-illustrated pressure-reducing unit to start the suction holding of the wafer WF on the support surfaces 18A, 19B. Thereafter, the sheet pasting unit 10 drives the linear motor 17 to move the wafer carrier table 18 leftward, and when the wafer WF reaches a predetermined position, the sheet pasting unit 10 drives the rotary motor 15A to feed out the raw is sheet RS in pace with the moving speed of the wafer WF. Consequently, the adhesive sheet AS is pasted on the upper surface of the wafer WF by being pressed by the press roller 14 while released from the release liner RL at the releasing edge 13A of the releasing plate 13, as indicated by the two-dot chain line in FIG. 1B. After the entire adhesive sheet. AS is pasted on the wafer WF, when a predetermined length of a feeding-direction leading end portion of the next adhesive sheet AS is released from the release liner RL at the releasing edge 13A of the releasing plate 13, the sheet pasting unit 10 stops driving the rotary motor 15A.

Next, when the wafer WF on which the entire adhesive sheet AS is pasted reaches a predetermined position on the left of the press roller 14, the sheet pasting unit 10 stops driving the linear motor 17 and then stops driving the not-illustrated pressure-reducing unit to cancel the suction holding of the wafer WF on the support surface 18A. Then, the sheet pasting unit 10 drives the direct-acting motor 19 to lift up the lift table 19A to separate the wafer WF from the support surface 18A as indicated by the two-dot chain line in FIG. 1B. Then, the wafer carrier unit 60 drives the multi joint robot 21 to bring the suction arm 61 into contact with the lower surface of the wafer WF, and thereafter drives the not-illustrated pressure-reducing unit to start the suction holding of the wafer WF by the suction arm 61. Next, when the sheet pasting unit 10 stops driving the not-illustrated pressure-reducing unit to cancel the suction holding of the wafer WF on the support surface 19B, the wafer carrier unit 60 drives the multi joint robot 21 to separate the wafer WF on which the adhesive sheet AS is pasted, from the support surface 19B. Thereafter, the sheet pasting unit 10 drives the linear motor 17 and the direct-acting motor 19 to return the wafer carrier table 18 and the lift table 19A to the initial positions.

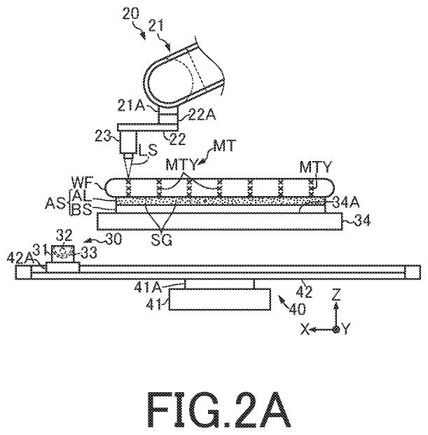

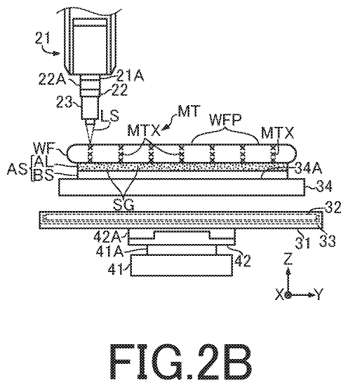

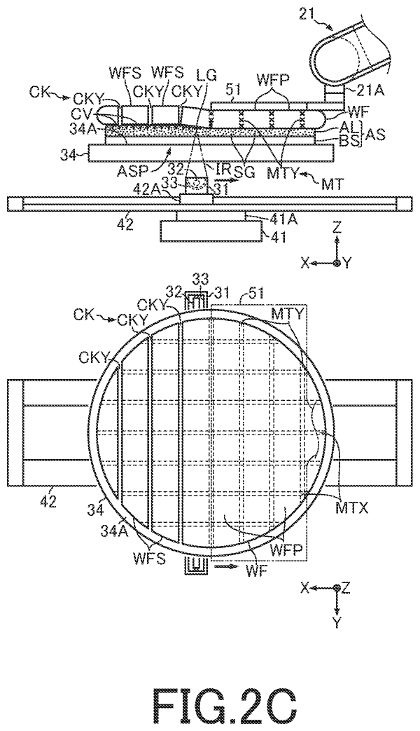

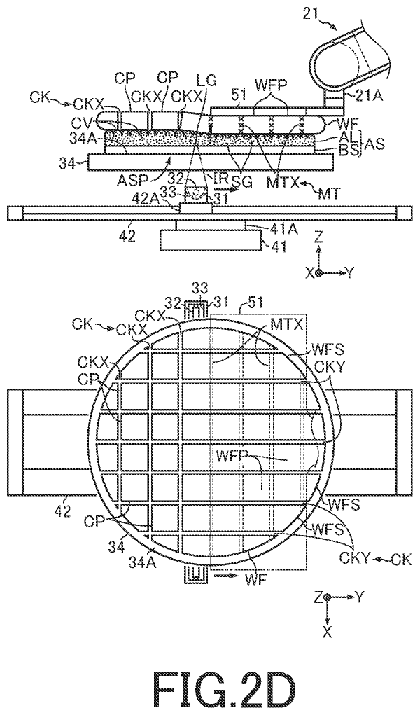

Thereafter, the wafer carrier unit 60 drives the multi joint robot 21 to turn the suction arm 61 upside down and places, on the support table 34, the wafer WF on which the adhesive sheet AS is pasted, with the adhesive sheet AS side facing the support table 34. Then, the dividing unit 30 drives the not-illustrated pressure-reducing unit to start the suction holding of the wafer WF on the support surface 34A. Next, the wafer carrier unit 60 stops driving the not-illustrated pressure-reducing unit to cancel the suction holding of the wafer WF by the suction arm 61, and thereafter drives the multi joint robot 21 to return the suction arm 61 to the initial position. Then, the tip arm 21A is pulled out from the suction arm holding part 61A and then inserted to the laser holding part 22A, so that the laser irradiator 23 is held by the multi-joint robot 21. Then, the modified part forming unit 20 drives the multi-joint robot 21 and the laser irradiator 23, and moves the laser irradiator 23 in the front-rear direction to form the first modified parts MTY in the wafer WF as illustrated in FIG. 2A, and then moves the laser irradiator 23 in the left-right direction to form the second modified parts MTX in the wafer WF, thereby forming the predefined discrete piece areas WFP as illustrated in FIG. 2B. Next, after the modified part forming unit 20 drives the multi-joint robot 21 to return the laser irradiator 23 to the initial position, the tip arm 21A is pulled out from the laser holding part 22A and then is inserted to the hold plate holding part 51A, so that the hold plate 51 is held by the multi -joint robot 21.

Thereafter, the dividing unit 30 and the moving unit 40 drive the light emitter 32 and the linear motor 42, and after the line-shaped application area LG extending in the Y-axis direction is formed, the light source box 31 is moved from left to right as illustrated in FIG. 2C, so that the line-shaped application area LG is moved while in parallel with the Y-axis direction. As a result, the swell grains SG contained in the adhesive sheet parts ASP to which the infrared rays IR have been applied swell one after another as to illustrated in FIG. 2C, so that innumerable convexities CV are formed on the adhesive layer AL. Consequently, the wafer WF is displaced up successively in order from its left parts to its right parts, so that cracks CKY extending in the Y-axis direction are formed with the first modified parts MTY serving as starting points, and strip-shaped wafers WFS extending in the Y-axis is direction are formed.

Note that, in this embodiment, when forming the cracks CKY in the above-described manner, the dividing unit 30 radiates the infrared rays IR such that each of the swell grains SG contained in the adhesive sheet parts ASP irradiated with the infrared rays IR does not completely swell or such that not all of the swell grains SG contained in the adhesive sheet parts ASP irradiated with the infrared rays IR swell. Further, at the time of the above-described formation of the cracks CKY, the displacement inhibiting unit 50 drives the multi joint robot 21 to place the hold plate 51 over the predefined discrete piece areas WFP whose displacement is not intended, thereby preventing a failure to form the cracks CK starting from the modified parts MT.

Next, when the light source box 31 reaches a predetermined position on the right of the right end of the wafer WF, the dividing unit 30 and the moving unit 40 stop driving the light emitter 32 and the linear motor 42. Then, the moving unit 40 drives the rotary motor 41 to rotate the dividing unit 30 anticlockwise in a top view by 90 degrees in an XY plane. Next, the dividing unit 30 and the moving unit 40 drive the light emitter 32 and the linear motor 42, and after the line-shaped application area LG extending in the X-axis direction is formed, the light source box 31 is moved from the rear side toward the front side as illustrated in FIG. 2D, so that the line-application area LG is moved while in parallel with the X-axis direction. Consequently, as illustrated in FIG. 2D, the swell grains SG contained in the adhesive sheet parts ASP irradiated with the infrared rays IR swell to a greater size one after another, or a larger number of the swell grains SG contained in the adhesive sheet parts ASP irradiated with the infrared rays IR swell, so that the innumerable convexities CV formed in the adhesive layer AL are enlarged. Consequently, the strip-shaped wafers WFS are partly displaced up one after another in order from the rear-side ones to the front-side ones, so that cracks CKX extending in the X-axis direction are formed with the second modified parts MTX serving as starting points, and is the plurality of chips CP each surrounded by the cracks CKX and the previously formed cracks CKY are formed. At this time as well, the displacement inhibiting unit 50 drives the multi-joint robot 21 to place the hold plate 51 over the predefined discrete piece areas WFP whose displacement is not intended.

Next, when the light source box 31 reaches a predetermined position on the front side of a front end of the wafer WF, the dividing unit 30 stops driving the light emitter 32, and then the moving unit 40 drives the rotary motor 41 and the linear motor 42 to return the light source box 31 to the initial position. Thereafter, after the displacement inhibiting unit 50 drives the multi-joint robot 21 to return the hold plate 51 to the initial position, the tip arm 21A is pulled out from the hold plate holding part 51A and the arms including the tip arm 21A are returned to the initial positions. Next, a not-illustrated chip carrier unit such as a pickup device or a holding device or the user detaches all the chips CP or a predetermined number of the chips CP from the adhesive sheet AS and carries the chips CP to another process. Then, the dividing unit 30 stops driving the not-illustrated pressure-reducing unit to cancel the suction holding of the adhesive sheet AS on the support surface 34A, thereafter the user or a not-illustrated removing unit removes the adhesive sheet. AS from the top of the support table 34, and the same operation as above is thereafter repeated.

The embodiment described above forms the chips CP by displacing the predefined discrete piece areas WFP by swelling the swell grains SG contained in the adhesive sheet AS, and thus is capable of forming the chips CP by dividing the wafer WF into pieces while applying as little tension as possible to the adhesive sheet AS.

The invention is by no means limited to the above units and processes as long as the above operations, functions, or processes of the units and processes are achievable, still less to the above merely exemplary structures and processes described in the exemplary embodiment. For instance, the modified part forming unit may be any modified part forming unit within the technical scope in light of the common general technical knowledge at the time of the filing of the application as long as it is capable of forming the modified parts in the work to form, in the work, the predefined discrete piece areas each surrounded by the modified parts or surrounded by the modified parts and an outer edge of the work (the same applies to other units and processes).

The sheet pasting unit 10 may feed out a raw sheet RS in which incisions are formed in a closed-loop shape or all along the short width direction in a band-shaped adhesive sheet base temporarily bonded to the release liner RL and a predetermined area demarcated by the incisions is the adhesive sheet AS, or a raw sheet RS in which a band-shaped adhesive sheet base is temporarily bonded to the release liner RL may be adopted and a cutting unit may make incisions in a closed-loop shape or all along the short width direction in the adhesive sheet base to form a predetermined area demarcated by the incisions as the adhesive sheet AS. Further, instead of each of the rollers such as the support roller 11 and the guide rollers 12, a plate-shaped member, a shaft member, or the like may support or guide the raw sheet RS or the release liner RL, and the raw sheet RS may be supported in a fan-folded state instead of in the wound state. The recovering unit may recover the release liner RL in, for instance, a fan-folded state or in a state where it is torn by a shredder or the like, instead of in the wound state, or may simply accumulate it to recover it without winding or fan-folding it. The sheet pasting unit 10 may include a drive device having a holding member which holds the adhesive sheet AS released by the releasing plate 13 from a side opposite the adhesive surface, and may press the held adhesive sheet AS against the wafer WF to paste the adhesive sheet AS. When pasting the adhesive sheet AS on the wafer WF, the sheet pasting unit 10 may move the releasing plate 13, the press roller 14, and so on without moving the wafer WF or while moving the wafer WF. The sheet pasting unit 10 does not necessarily have to include the holding units in the support surfaces 18A, 19B, may paste the adhesive sheet AS on the wafer WF with the adhesive sheet AS set upside down or facing sideways, may paste the adhesive sheet AS on the wafer WF while the wafer WF is held and moved by the multi-joint robot 21 instead of by the linear motor 17 and the wafer carrier table 18, and may adopt a drive device as a press member contact/separation unit that brings the press roller 14 close to or away from the wafer WF to prevent the wafer WF from being given stress or damaged. If another device moves the wafer WF, the sheet pasting unit 10 need not include the linear motor 17, the wafer carrier table 18, the direct-acting motor 19, and so on.

When the modified part forming unit 20 forms the modified parts MT in the wafer WF, the wafer WF may be moved while the laser irradiator 23 is not moved or is moved. The modified part forming unit 20 may form one modified part MT or more parallel to the X-axis or the Y-axis, may form one modified part MT or more not parallel to the X-axis or the Y-axis, may form a plurality of modified parts MT at equal intervals or uneven intervals, may form a plurality of modified parts MT parallel or not parallel to each other, may form a plurality of modified parts MT not intersecting with each other, may form a plurality of modified parts MT orthogonally or obliquely intersecting with each other, may form one modified part MT or more in one different direction or in each of two different directions or more besides the first and second directions, and may form one curved or folded-line shaped modified part MT or more. The predefined discrete piece areas WFP and the chips CP formed by such modified parts MT may be in any shape such as a circular shape, an elliptical shape, a triangular shape, or a polygonal shape having four sides or more.

To form the modified parts MT, the modified part forming unit 20 may embrittle, pulverize, liquefy, or hollow the wafer WF by changing the characteristics, properties, nature, material, composition, structure, size, or the like of the wafer WF by applying laser light, an electromagnetic wave, vibration, heat, chemicals, a chemical substance, or the like. Such modified parts MT may be any as long as they make it possible to divide the work into pieces using the swelling of the swell grains SG as external force to form the discrete piece.

The modified part forming unit 20 may hold and move the laser irradiator 23 by a drive device not shared with the displacement inhibiting unit 50 and the wafer carrier unit 60. If the modified parts MT are formed in the wafer WF beforehand and the predefined discrete piece areas WFP each surrounded by the modified parts MT or surrounded by the modified parts MT and the outer edge of the wafer WF are formed beforehand, the discrete piece forming device EA of the present invention need not include the modified part forming unit 20.

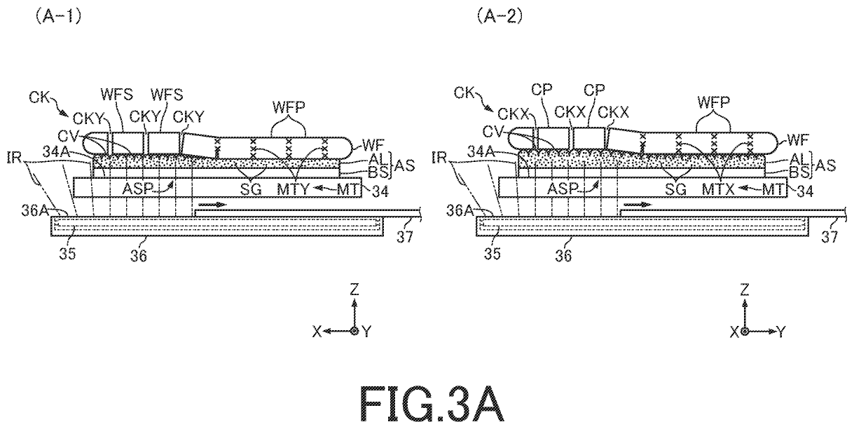

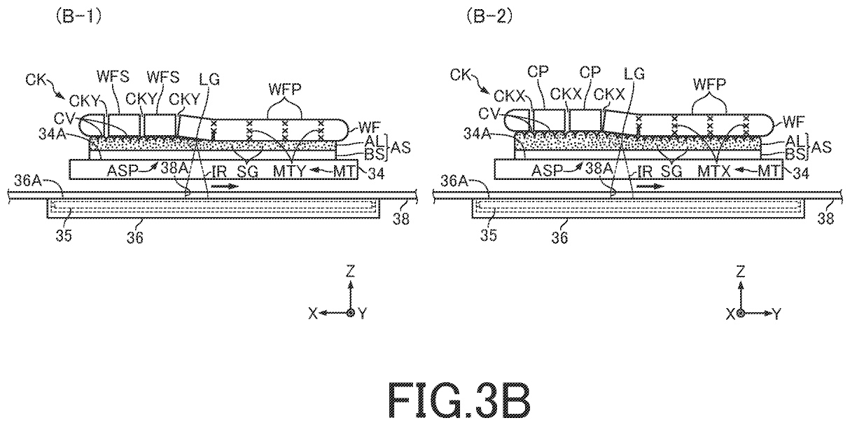

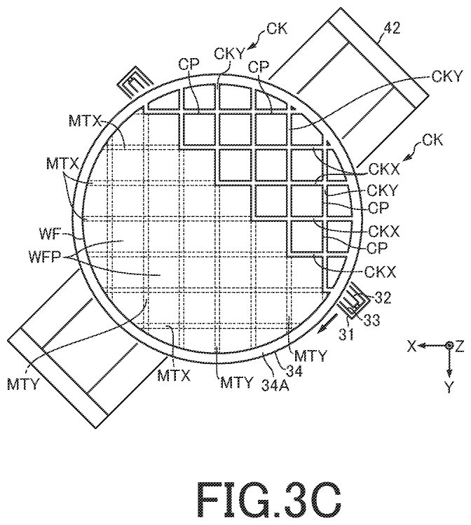

As illustrated in FIG. 3A, the dividing unit 30 may include a light emitter 35 capable of applying the infrared rays IR to the whole adhesive sheet AS at a time, a reflector plate 36 reflecting the infrared rays IR emitted by the light emitter 35, and an opening/closing plate 37 capable of opening/closing an opening 36A provided at the top of the reflector plate 36. In this case, the dividing unit 30 drives the light emitter 35 to cause it to emit the infrared rays IR and gradually moves the opening/closing plate 37, which completely closes the opening 36A at first, from left toward right, thereby forming the cracks CKY one after another in order from the left ones to the right ones to form the strip-shaped wafers WFS extending in the Y-axis direction as illustrated in (A-1) in FIG. 3A. Next, after completely closing the opening 36A with the opening/closing plate 37, the dividing unit 30 is rotated anticlockwise in the top view by 90 degrees in the XY plane. Thereafter, the dividing unit 30 gradually moves the opening/closing plate 37 from the rear side toward the front side to form the cracks CKX one after another in order from the rear ones to the front ones, thereby forming the chips CP by the cracks CKY and the cracks CKY as illustrated in (A-2) in FIG. 3A.

Instead of the opening/closing plate 37, the dividing unit 30 may adopt a moving plate 38 including a slit 38A through which the infrared rays IR emitted by the light emitter 35 are applied to form the line-shaped application area LG as illustrated in (B-1) and (B-2) in FIG. 3B. In the slit 38A, a lens that condenses or collimates the infrared rays IR may be provided. The opening plate 37 or the moving plate 38 may be provided on, for example, the support table 34.

The dividing unit 30 does not necessarily have to include the condenser plate 33 or the reflector plate 36, and may include a lens that condenses or collimates the infrared rays IR, instead of or in addition to the condenser plate 33. The irradiation duration of the adhesive sheet AS with the infrared rays IR may be decided appropriately in consideration of the characteristics, properties, nature, material, composition, structure, and so on of the swell grains SG. The light emitters 32, 35 of the dividing unit 30 each may be a LED (Light Emitting Diode) lamp, a high-pressure mercury lamp, a low-pressure mercury lamp, a metal halide lamp, a xenon lamp, a halogen lamp, or the like, or may be an appropriate combination of these. The dividing unit 30 may be one that applies, as the energy, laser light, an electromagnetic wave, vibration, heat, chemicals, a chemical substance, or the like or an appropriate combination of these. Any configuration of the dividing unit 30 may be adopted in consideration of the characteristics, properties, nature, material, combination, structure, and so on of the swell grains SG. The wafer WF on which the adhesive sheet AS is pasted may be placed on the support table 34 with the wafer WF side facing the support table 34. In this case, the dividing unit 30 may radiate the infrared rays IR from the side opposite the support table 34, and if the work is able to transmit the predetermined energy, the dividing unit 30 may apply the predetermined energy from the work side, from the adhesive sheet AS side, or from both of the work side and the adhesive sheet AS side.

In this embodiment, the dividing unit 30 forms the line-shaped application area LG and applies the infrared rays IR to parts of the adhesive sheet AS, but the dividing unit 30 may form a dotted application area so that the application area of the infrared rays JR becomes dotted and apply the infrared rays IR to parts of the adhesive sheet AS, may form a planar application area corresponding or not corresponding to the planar shape of the predefined discrete piece areas WFP and apply the infrared rays IR to parts of the adhesive sheet AS, or may, for example, apply the infrared rays IR only to part of the adhesive sheet part ASP corresponding to one section or more at an optional position or more out of the predefined discrete piece areas WIT, thereby displacing the predefined discrete piece areas WSP composed of the one section or more attached to the adhesive sheet part ASP, thereby forming the chips CP.

The support table 34 may be one without the holding unit, and if the work is unable to transmit the predetermined energy, the support table 34 is constituted by one able to transmit the predetermined energy, or if the work is able to transmit the predetermined energy, the support table 34 may be one unable to transmit the predetermined energy or may be one able to transmit the predetermined energy. If the multi-joint robot 21 holds the wafer WF or if another device supports the wafer WF, the discrete piece forming device EA of the present invention need not include the support table 34.

As illustrated in FIG. 3C, the moving unit 40 may move a line-shaped application area LG (not illustrated) obliquely intersecting with the first modified parts MTY and the second modified parts MTX from one end toward the other end of the wafer WF so that the cracks CKY, CKX starting both from the first and second modified parts MTY, MTX are formed simultaneously to form the chips CP (the adhesive sheet AS pasted on the wafer WF is not illustrated in FIG. 3C). The oblique intersection angle in this case may be any, and for example, may be 1 degree, 5 degrees, 10 degrees, 45 degrees, 60 degrees, 89 degrees, or the like to the X-axis or the Y-axis.

The wafer WF may be moved while the dividing unit 30 is moved or is not moved by the moving unit 40 when the wafer WF is rotated anticlockwise in the top view by 90 degrees in the XY plane relative to the dividing unit 30, and when the line-shaped application area LG is moved to be parallel to the Y-axis direction and to be parallel to the X-axis direction, or when the line-shaped application area LG is moved not to be parallel to the X-axis or Y-axis direction. At least one of the dividing unit 30 and the wafer WF may be moved from right toward left, at least one of the dividing unit 30 and the wafer WF may be moved from the front side toward the rear side, at least one of the dividing unit 30 and the wafer WF may be moved from another direction toward still another direction, at least one of the dividing unit 30 and the wafer WF may be rotated clockwise in the top view by 90 degrees in the XY plane, and at least one of the dividing unit 30 and the wafer WF may be rotated by 90 degrees or less or by 90 degrees or more in the XY plane. The moving unit 40 may be a structure included in the discrete piece forming device EA of the present invention, or if another device moves at least one of the wafer WF and the dividing unit 30, the moving unit 40 need not be included in the discrete piece forming device EA of the present invention. For example, if the predefined discrete piece area WFP is formed only at one place of the wafer WF and the dividing unit 30 forms a planar application area corresponding to or not corresponding to the planar shape of this predefined discrete piece area WFP and applies the infrared rays IR to part of the adhesive sheet AS to form one chip CP, the discrete piece forming device EA of the present invention need not include the moving unit 40, either.

The displacement inhibiting unit 50 may place the hold plate 51 in contact or in non-contact with the tops of the predefined discrete piece areas WFP whose displacement is not intended. The displacement inhibiting unit 50 may inhibit the displacement of the wafer WF that has not yet been displaced by the dividing unit 30, by a different method such as by spraying gas or by pulleys and a belt, may hold and move the hold plate 51 with a drive device that is not shared with the modified part forming unit 20 and the wafer carrier unit 60, may adopt a drive device that moves the hold plate 51 in one direction (for example, the left-right direction) and another drive device that moves another hold plate in another direction (for example, the is front-rear direction). The discrete piece forming device EA of the present invention does not necessarily have to include the displacement inhibiting unit 50.

The wafer carrier unit 60 may hold and move the suction arm 61 with a drive device that is not shared with the modified part forming unit 20 and the displacement inhibiting unit 50. If another device moves the wafer WF on which the adhesive sheet AS is pasted, the discrete piece forming device EA of the present invention need not include the wafer carrier unit 60.

For example, the swell grains SG may include not-illustrated first swell grains that are swollen by 80° C. heat energy as first energy and not-illustrated second swell grains that are swollen by 120° C. heat energy as second energy. In this case, the dividing unit 30 includes: a first dividing unit that applies the 80° C. heat energy and a second dividing unit that applies the 120° C. heat energy. In this case, the dividing unit 30 is capable of forming the chips CP by forming the cracks CKY starting from the first modified parts MTY by applying the 80° C. heat energy and thereafter forming the cracks CKX starting from the second modified parts MIX by applying the 120° C. heat energy, by the same operation as that of the above-described embodiment. The first energy and the second energy may be heat energy at any temperature. If the swell grains SG include other swell grains that are swollen by heat energy at a temperature different from those of the first energy and the second energy, the dividing unit 30 may further include another dividing unit that applies the heat energy at this different temperature.

Further, the swell grains SO contained in the adhesive sheet AS may include not-illustrated first swell grains that are swollen by infrared rays as first energy and not-illustrated second swell grains that are swollen by ultraviolet rays as second energy. In this case, the dividing unit 30 may include a not-illustrated first dividing unit that applies the infrared rays and a not-illustrated second dividing unit that applies the ultraviolet rays. In this case, the dividing unit 30 may form the chips CP by forming the cracks CKY starting from the first modified parts MTY by applying the infrared rays and thereafter forming the cracks CKX starting from the second modified parts MIX by applying the ultraviolet rays, by the same operation as that of the above-described embodiment. If the adhesive sheet AS contains other swell grains that are swollen by different energy from the first energy and the second energy, the dividing unit 30 may further include another dividing unit that applies the different energy.

Further, in the above-described embodiment, the line-shaped application area LG is gradually moved from one end toward the other end of the wafer WF, but to form the cracks CK starting from the modified parts MT, the dividing unit 30 may be moved such that the line-shaped application area LG is located only at a position where the modified part MT is formed, or the light emitter 32 or 35, which has been kept off, may be driven after the dividing unit 30 or the slit 38A is moved such that the line-shaped application area LG is located at the position where the modified part MT is formed.

Further, the swell grains SG contained in the adhesive sheet AS may be those that swell when exposed to an electromagnetic wave such as ultraviolet rays, visible rays, an acoustic wave, X-rays, or gamma rays, heat of hot water or hot air, or the like as the predetermined energy. The dividing unit 30 may be any as long as it can divide the work into pieces to form the discrete pieces by swelling the swell grains SG in consideration of the characteristics, properties, nature, material, composition, structure, or the like of these swell grains SG.

The discrete piece forming device EA may be configured such that the carrier unit or the user carries the chips CP including the adhesive sheet AS to another process without removing the chips CP from the adhesive sheet AS.

In the adhesive sheet AS, the swell grains SG may be contained only in the base BS forming the adhesive sheet AS or may be contained in both of the adhesive layer AL and the base BS. The adhesive sheet AS may be one that further includes one intermediate layer or more between the adhesive layer AL and the base BS, with the swell grains SG contained in at least one or at least two of the intermediate layer, the adhesive layer AL, and the base BS. In the wafer WF, the adhesive sheet AS may be pasted on a surface on which a circuit is formed, may be pasted on a surface on which a circuit is not formed, or may be pasted on each of the surfaces. If the adhesive sheet AS is thus pasted on each of the surfaces of the wafer WF, these adhesive sheets AS may be the same or may be different, and it is also acceptable that one of the adhesive sheets does not contain the swell grains SG. The adhesive sheet AS or an adhesive sheet different from the adhesive sheet AS may be pasted on a surface in contact with the support surfaces 18A, 19B in advance. If the adhesive layer AL and the base BS both contain the swell grains SG and if at least two of the intermediate layer, the adhesive layer AL, and the base BS contain the swell grains SG, these swell grains SG may be the same or may be different. When the dividing unit 30 forms the chips CP, an obstructive adhesive sheet may be released from the wafer WF by a known releasing unit before the dividing unit 30 applies the external force.

The discrete pieces are not limited to the chips CP, and for example, may be strip-shaped wafers WFS, and in this case, the predefined discrete piece areas are areas each surrounded by the first modified parts MTY and the outer edge of the wafer WF, and the moving unit 40 only need to move the line-shaped application area LG formed by the dividing unit 30 only in one direction (for example, the Y-axis direction, the X-axis direction, or another direction).

If the work is formed in the shape of the strip-shaped wafer WFS beforehand, the moving unit 40 may move the line-shaped application area LG formed by the dividing unit 30 only in one direction (for example, the Y-axis direction, the X-axis direction, or the other direction) at the time of the formation of the chips CP.

The predefined discrete piece area may be one surrounded by the modified parts MT and the outer edge of the wafer WF, and the shape of a discrete piece formed from such a predefined discrete piece area may be any, for example, a substantially fan shape formed by one side parallel to the X-axis, one side parallel to the Y-axis, and the outer edge of the wafer WF or a shape formed by two sides parallel to the X-axis, one side parallel to the Y-axis, and the outer edge of the wafer WF.

As the swell grains SG, grains each having an elastic shell encapsulating a substance, such as isobutane, propane, or pentane, that is easily gasified to swell by heat can be exemplified, and examples of the swell grains SG include, but are not limited to, the thermally foamable grains disclosed in Japanese Patent Application No. 2017-73236, Japanese Patent Application Laid-open No. 2013-159743, Japanese Patent Application Laid-open No. 2012-167151, Japanese Patent Application Laid-open No. 2001-123002, and so on which are explicitly incorporated in the present specification by reference and the swell grains disclosed in Japanese Patent Application Laid-open No. 2013-47321, Japanese Patent Application Laid-open No. 2007-254580, Japanese Patent Application Laid-open No. 2011-212528, Japanese Patent Application Laid-open No. 2003-261842, and so on which are explicitly incorporated in the present specification by reference. For example, a foaming agent that generates water, carbonic acid gas, or nitrogen through pyrolysis to exhibit a similar effect to that of the swell grains may be adopted. Also adoptable are those whose shells are swollen by a gas generating agent such as an azo compound which generates gas when exposed to ultraviolet rays, as disclosed in Japanese Patent Application Laid-open No. 2016-53115 and Japanese Patent Application Laid-open No. H07-278333 which are explicitly incorporated in the present specification by reference, or for example, those that are swollen by heating, such as rubber or resin, or baking soda, sodium acid carbonate, baking powder, or the like.

In the wafer WF, a predetermined circuit may be formed on at least one of one surface and the other surface, or it is also acceptable that a circuit is formed on neither of these surfaces.

The adhesion of the adhesive sheet AS to the chips CP may be reduced by the reduction in its adhesion area to the chips CP owing to the formation of the innumerable convexities CV, or its adhesion to the chips CP does not necessarily have to be reduced. To facilitate the detachment of the chips CP by reducing its adhesion to the chips CP, the adhesive sheet AS may be one that is reduced in adhesion of the adhesive layer AL by adhesion reducing energy such as, for example, an electromagnetic wave such as infrared rays, ultraviolet rays, visible rays, an acoustic wave, X-rays, or gamma rays, hot water, hot air, or the like. In this case, an adhesion reducing energy applying unit that radiates the adhesion reducing energy is adopted, and the adhesion reducing energy applying unit radiates the adhesion reducing energy to the adhesive sheet AS before the chips CP are detached from the adhesive sheet AS.

The discrete piece forming device EA may include a known polishing (grinding) unit which polishes (grinds) the wafer WF to a predetermined thickness, may include a known pickup unit which detaches the chips CP from the adhesive sheet AS, and may include a known bonding unit which bonds the chips CP detached from the adhesive sheet AS to another member such as a substrate or a mount.

The materials, types, shapes, and so on of the adhesive sheet AS and the work in the present invention are not limited. For example, the adhesive sheet AS may be in a circular shape, an elliptical shape, a polygonal shape such as a triangular shape or a quadrangular shape, or any other shape, and may be of a pressure-sensitive bonding type or a heat-sensitive bonding type. If the adhesive sheet AS is of the heat-sensitive bonding type, it may be bonded by an appropriate method, for example, by an appropriate heating unit for heating the adhesive sheet AS, such as a coil heater or a heating side of a heat pipe. Further, such an adhesive sheet AS may be, for example, a single layer adhesive sheet having only the adhesive layer AL, an adhesive sheet having an intermediate layer between the base BS and the adhesive layer AL, a three or more-layer adhesive sheet having a cover layer on the upper surface of the base BS, or an adhesive sheet such as what is called a double-faced adhesive sheet in which the base BS can be released from the adhesive layer AL. The double-faced adhesive sheet may be one having one intermediate layer or more, or may be a single-layer one or a multilayer one not having an intermediate layer. Further, the work may be, for example, a single item such as food, a resin container, a semiconductor wafer such as a silicon semiconductor wafer or a compound semiconductor wafer, a circuit board, an information recording substrate such as an optical disk, a glass plate, a steel sheet, pottery, a wood board, or a resin, or may be a composite made up of two of these or more, and it may also be a member, an article, or the like of any form. The adhesive sheet AS may be read as one indicating its function or application, and may be, for example, any sheet, film, tape, or the like such as an information entry label, a decoration label, a protect sheet, a dicing tape, a die attach film, a die bonding tape, or a recording layer forming resin sheet.

The drive device in the above-described embodiment may be an electric machine such as a rotary motor, a direct-acting motor, a linear motor, a uniaxial robot, a multi-joint robot having two joints or three or more joints, an actuator such as an air cylinder, a hydraulic cylinder, a rodless cylinder, or a rotary cylinder, or the like, or may be one in which some of these are directly or indirectly combined.

In the above-described embodiment, in the case where a rotating member such as a roller is used, a drive device that drives the rotation of the rotating member may be provided, and the surface of the rotating member or the rotating member itself may be formed of a deformable member such as rubber or resin or may be formed of a non-deformable member. Another member such as a shaft or a blade that rotates or does not rotate may be adopted instead of the roller. In a case where a presser such as a press unit or a press member such as a press roller or a press head, that presses an object to be pressed is adopted, a member such as a roller, a round bar, a blade member, rubber, resin, or sponge may be adopted or a structure that sprays gaseous substance such as the atmospheric air or gas for pressing may be adopted, instead of or in addition to those exemplified in the above, and the presser may be formed of a deformable member such as rubber or resin or may be formed of a non-deformable member. In a case where a releaser such as a releasing unit or a releasing member such as a releasing plate or a releasing roller, that releases an object to be released is adopted, a member such as a plate-shaped member, a round bar, or a roller may be adopted instead of or in addition to those exemplified above, and the releaser may be formed of a deformable member such as rubber or resin or may be formed of a non-deformable member. In a case where a member such as a support (holding) unit or a support (holding) member, that supports or holds a member to be supported is adopted, the member to be supported may be supported (held) by a gripping unit such as a mechanical chuck or a chuck cylinder, Coulomb force, an adhesive (adhesive sheet, adhesive tape), a tackiness agent (tacky sheet, tacky tape), magnetic force, Bernoulli adsorption, suction/adsorption, a drive device, or the like. In a case where one such as a cutting unit or a cutting member, that cuts a member to be cut or forms an incision or a cutting line in a member to be cut is adopted, one that cuts with a cutter blade, a laser cutter, ion beams, thermal power, heat, water pressure, a heating wire, or the spraying of gas, liquid, or the like may be adopted instead of or in addition to those exemplified above. Further, an appropriate combination of drive devices may move one that cuts the object to be cut at the time of the cutting.

What is claimed is:

1. A discrete piece forming device comprising:
a sheet pasting unit which pastes, on a work, an adhesive sheet containing a swell grain that swells when predetermined energy is applied;
a modified part forming unit which forms a modified part in the work to form, in the work, a predefined discrete piece area surrounded by the modified part or surrounded by the modified part and an outer edge of the work; and
a dividing unit which divides the work into pieces by forming, in the work, a crack starting from the modified part by applying external force to the work, to form a discrete piece, wherein the dividing unit applies the energy to part of the adhesive sheet to swell the swell grain contained in an adhesive sheet part to which the energy has been applied, thereby displacing the predefined discrete piece area pasted on the adhesive sheet part to form the discrete piece.

2. The discrete piece forming device of claim 1, further comprising
a moving unit which relatively moves the work and the dividing unit.

3. The discrete piece forming device of claim 2,
wherein the modified part includes a first modified part extending along a first direction and a second modified part extending along a second direction intersecting with the first direction,
wherein the dividing unit forms a line-shape application area in which an application area of the energy extends in a predetermined direction, at a position to which the energy is applied, and
wherein the moving unit moves the line-shaped application area to make the line-shaped application area parallel to the first direction, and further moves the line-shaped application area to make the line-shaped application area parallel to the second direction.

4. The discrete piece forming device of claim 1,
wherein the swell grain comprises:
a first swell grain that is swollen by first energy; and
a second swell grain that is swollen by second energy, and
wherein the dividing unit comprises:
a first dividing unit that applies the first energy; and
a second dividing unit that applies the second energy.

5. The discrete piece forming device of claim 1, further comprising
a displacement inhibiting unit which inhibits the displacement of part, of the work, that has not yet been displaced by the dividing unit.

6. The discrete piece forming device of claim 2,
wherein the swell grain comprises:
a first swell grain that is swollen by first energy; and
a second swell grain that is swollen by second energy, and
wherein the dividing unit comprises:
a first dividing unit that applies the first energy; and
a second dividing unit that applies the second energy.

7. The discrete piece forming device of claim 3,
wherein the swell grain comprises:
a first swell grain that is swollen by first energy; and
a second swell grain that is swollen by second energy, and
wherein the dividing unit comprises:
a first dividing unit that applies the first energy; and
a second dividing unit that applies the second energy.

8. The discrete piece forming device of claim 1, further comprising
a displacement inhibiting unit which inhibits the displacement of part, of the work, that has not yet been displaced by the dividing unit.

9. The discrete piece forming device of claim 2, further comprising
a displacement inhibiting unit which inhibits the displacement of part, of the work, that has not yet been displaced by the dividing unit.

10. The discrete piece forming device of claim 3, further comprising
a displacement inhibiting unit which inhibits the displacement of part, of the work, that has not yet been displaced by the dividing unit.

11. The discrete piece forming device of claim 4, further comprising
a displacement inhibiting unit which inhibits the displacement of part, of the work, that has not yet been displaced by the dividing unit.

12. The discrete piece forming device of claim 6, further comprising
a displacement inhibiting unit which inhibits the displacement of part, of the work, that has not yet been displaced by the dividing unit.

13. A discrete piece forming device comprising:
a sheet pasting unit which pastes an adhesive sheet containing a swell grain that swells when predetermined energy is applied, on a work in which a modified part is formed beforehand and a predefined discrete piece area surrounded by the modified part or surrounded by the modified part and an outer edge of the work is formed beforehand; and
a dividing unit which divides the work into pieces by forming, in the work, a crack starting from the modified part by applying external force to the work, to form a discrete piece, wherein the dividing unit applies the energy to part of the adhesive sheet to swell the swell grain contained in an adhesive sheet part to which the energy has been applied, thereby displacing the predefined discrete piece area pasted on the adhesive sheet part to form the discrete piece.

14. The discrete piece forming device of claim 13, further comprising
a moving unit which relatively moves the work and the dividing unit.

15. The discrete piece forming device of claim 14,
wherein the modified part includes a first modified part extending along a first direction and a second modified part extending along a second direction intersecting with the first direction,
wherein the dividing unit forms a line-shape application area in which an application area of the energy extends in a predetermined direction, at a position to which the energy is applied, and
wherein the moving unit moves the line-shaped application area to make the line-shaped application area parallel to the first direction, and to further moves the line-shaped application area to make the line-shaped application area parallel to the second direction.

16. The discrete piece forming device of claim 13,
wherein the swell grain comprises:
a first swell grain that is swollen by first energy; and
a second swell grain that is swollen by second energy, and
wherein the dividing unit comprises:
a first dividing unit that applies the first energy; and
a second dividing unit that applies the second energy.

17. The discrete piece forming device of claim 13, further comprising
a displacement inhibiting unit which inhibits the displacement of part, of the work, that has not yet been displaced by the dividing unit.

18. The discrete piece forming device of claim 14,
wherein the swell grain comprises:
a first swell grain that is swollen by first energy; and
a second swell grain that is swollen by second energy, and
wherein the dividing unit comprises:
a first dividing unit that applies the first energy; and
a second dividing unit that applies the second energy.

19. The discrete piece forming device of claim 15,
wherein the swell grain comprises:
a first swell grain that is swollen by first energy; and
a second swell grain that is swollen by second energy, and
wherein the dividing unit comprises:
a first dividing unit that applies the first energy; and
a second dividing unit that applies the second energy.

20. The discrete piece forming device of claim 13, further comprising
a displacement inhibiting unit which inhibits the displacement of part, of the work, that has not yet been displaced by the dividing unit,

21. The discrete piece forming device of claim 14, further comprising
a displacement inhibiting unit which inhibits the displacement of part, of the work, that has not yet been displaced by the dividing unit.

22. The discrete piece forming device of claim 15, further comprising
a displacement inhibiting unit which inhibits the displacement of part, of the work, that has not yet been displaced by the dividing unit.

23. The discrete piece forming device of claim 16, further comprising
a displacement inhibiting unit which inhibits the displacement of part, of the work, that has not yet been displaced by the dividing unit.

24. The discrete piece forming device of claim 18, further comprising
a displacement inhibiting unit which inhibits the displacement of part, of the work, that has not yet been displaced by the dividing unit

25. A discrete piece forming method comprising:
a sheet pasting step of pasting, on a work, an adhesive sheet containing a swell grain that swells when predetermined energy is applied;
a modified part forming step of forming a modified part in the work to form, in the work, a predefined discrete piece area surrounded by the modified part or surrounded by the modified part and an outer edge of the work; and
a dividing step of dividing the work into pieces by forming, in the work, a crack starting from the modified part by applying external force to the work, to form a discrete piece, wherein the dividing step includes applying the energy to part of the adhesive sheet to swell the swell grain contained in an adhesive sheet part to which the energy has been applied, thereby displacing the predefined discrete piece area pasted on the adhesive sheet part to form the discrete piece.

26. A discrete piece :forming method comprising,
a sheet pasting step of pasting an adhesive sheet containing a swell grain that swells when predetermined energy is applied, on a work in which a modified part is formed beforehand and a predefined discrete piece area surrounded by the modified part or surrounded by the modified part and an outer edge of the work is formed beforehand; and
a dividing step of dividing the work into pieces by forming, in the work, a crack starting from the modified part by applying external force to the work, to form a discrete piece, wherein the dividing step includes applying the energy to part of the adhesive sheet to swell the swell grain contained in an adhesive sheet part to which the energy has been applied, thereby displacing the predefined discrete piece area pasted on the adhesive sheet part to form the discrete piece.
